(19) United States
(12) Patent Application Publication
(10) Pub. No.: US 2006/0216949 A1
(43) Pub. Date: Sep. 28, 2006

(54) Method for cleaning heat treatment apparatus

(76) Inventors: Kazuhide Hasebe, Tokyo-To (JP); Mitsuhiro Okada, Tokyo-To (JP); Takashi Chiba, Tokyo-To (JP); Jun Ogawa, Tokyo-To (JP)

Correspondence Address: SMITH, GAMBRELL & RUSSELL, 1850 M STREET, N.W., SUITE 800, WASHINGTON, DC, 20036, US

(21) Appl. No.: 10/553,828

(22) PCT Filed: Apr. 20, 2004
(86) PCT No.: PCT/JP04/05644

§ 371 Date: Oct. 20, 2005

(30) Foreign Application Priority Data
Apr. 22, 2003 (JP) 2003-117663

(51) Int. Cl. H01L 21/31; H01L 21/469

(52) U.S. Cl. 438/770

(57) ABSTRACT

The present invention is a method of cleaning a heat treatment apparatus that deposits an SiO₂ film by mean of TEOS on an object to be processed contained in a treatment vessel capable of forming a vacuum. In the cleaning method, the heat treatment apparatus is cleaned by supplying an HF gas and an NH₃ gas into the treatment vessel.

### BACKGROUND OF THE INVENTION

1. Field of the Invention

The present invention relates to a method of cleaning a heat treatment apparatus that deposits a film on an object to be processed such as a semiconductor wafer.

2. Background Art

When a semiconductor integrated circuit is manufactured, a semiconductor wafer is generally subjected to various treatments such as a film-deposition treatment and an etching treatment. For example, when manufacturing a semiconductor integrated circuit in a CVD apparatus for simultaneously depositing films on the surface of a plurality of wafers, semiconductor wafers are placed at equal pitches on a wafer boat made of quartz. Then, the wafer boat is loaded in a treatment vessel, and is heated to a predetermined temperature under a reduced pressure. At the same time, a treatment gas is supplied onto a surface of each of the wafers, so that a decomposition product or a reaction product of the treatment gas is deposited on the wafer.

In this manner, a film-deposition treatment is applied to a wafer surface. However, during the film-deposition treatment, in addition to a wafer surface on which a film should be deposited, a film is unnecessarily deposited on a part where a film-deposition is not intended, such as a surface of a wafer boat and an inner surface of a treatment vessel. This unnecessary deposited film generates particles floating in a CVD apparatus, which may cause a defect in a semiconductor integrated circuit. Thus, a CVD apparatus is regularly or irregularly subjected to a cleaning treatment, in order to remove such unnecessary film.

The cleaning treatment is required not only in a so-called hot wall LP-CVD (Chemical Vapor Deposition) apparatus of a batch type which is described above, but also in a sheet-fed-type film deposition apparatus where a wafer is treated one by one.

Conventionally, a hot wall LP-CVD apparatus, irrespective of lateral or vertical type, has been regularly subjected to a cleaning treatment based on a wet cleaning method where a cleaning liquid is used, in order to eliminate unnecessary film deposited on an inner wall of a treatment vessel or the like. However, a dry cleaning method using a cleaning gas (etching gas) has been recently employed, because the method enables an in-site cleaning treatment, without disassembling an LP-CVD apparatus. A dry cleaning method using, e.g., a ClF₃ gas as an etching gas has been proposed (Japanese Patent Laid-Open Publication Nos. 31479/1991, 155827/1992, and 151396/1994). According to this cleaning method, a gas including, e.g., ClF₃ is introduced as a cleaning gas into a treatment vessel so as to remove unnecessary film deposited on a surface of a wafer boat, an inner surface of the treatment vessel, and so on. Alternatively, an HF gas may be used as a cleaning gas, depending on the kind of unnecessary film to be removed.

In a cleaning treatment, it is important to efficiently etch unnecessary film to remove the same, without damaging structural members of a heat treatment apparatus, such as a treatment vessel and a wafer boat. Thus, an excellent etching gas is a gas which has a higher selectivity for a material forming a treatment vessel or the like, and for a film to be removed by etching. That is, it is preferable to use an etching gas that can easily react with a film to be removed by etching so as to efficiently remove the same, while the gas does not react with a material forming a structural member such as a treatment vessel or the like.

However, in a case where a material forming a treatment vessel, a wafer boat, and so on, is similar to, or the same kind of material forming unnecessary film to be removed by etching, a selectivity of an etching gas is narrowed. In this case, a treatment vessel or the like is prone to be damaged by a cleaning treatment. For example, when a silicon oxide (SiO₂) film is deposited on a surface of a semiconductor wafer by using TEOS (tetraethyl orthosilicate) in a heat treatment apparatus provided with a treatment vessel and a wafer boat each of which is made of quartz, a constituent material of the treatment vessel and the wafer boat and unnecessary film deposited on surfaces thereof are mainly formed of SiO₂, although densities of molecules are different from each other.

In these circumstances, an HF gas as a cleaning gas has been conventionally used independently, or together with an inert gas as a carrier gas. However, since an etching rate (synonymous with cleaning rate) of the HF gas with respect to an SiO₂ film deposited by using TEOS is not sufficiently high, it takes a long time for a cleaning treatment. In addition, due to an insufficient etching rate, an end point of a cleaning treatment which is previously calculated may be significantly different from an actual end point of a cleaning treatment at which unnecessary film is fully eliminated. An overetching damages structural members such as a treatment vessel, a wafer boat, and a heat-insulation cylinder, so that durability of these members may be shortened.

### SUMMARY OF THE INVENTION

The present invention has been made in view of the foregoing problems so as to effectively solve the same. An object of the present invention is to provide a method of cleaning a heat treatment apparatus, in which unnecessary silicon oxide film formed by TEOS which is deposited on structural members of the heat treatment apparatus can be efficiently, rapidly removed at a high etching rate, so that a throughput can be improved, while damage to the structural members can be restrained.

Further, another object of the present invention is to provide a method of cleaning a heat treatment apparatus, in which unnecessary arsenic silicate glass film formed by TEOS which is deposited on structural members of the heat treatment apparatus can be efficiently, rapidly removed at a high etching rate, so that a throughput can be improved, while damage to the structural members can be restrained.

Furthermore, another object of the present invention is to provide a method of cleaning a heat treatment apparatus, in which unnecessary boron silicate glass film formed by TEOS which is deposited on structural members of the heat treatment apparatus can be efficiently, rapidly removed at a high etching rate, so that a throughput can be improved, while damage to the structural members can be restrained.

The present invention is a method of cleaning a heat treatment apparatus that deposits an SiO₂ film by means of TEOS on an object to be processed contained in a treatment vessel capable of forming a vacuum, the method comprising the step of: cleaning the heat treatment apparatus by supplying an HF gas and an NH₃ gas into the treatment vessel.

According to the present invention, a mixed gas of an HF gas and an NH₃ gas operating as a cleaning gas can rapidly, efficiently remove unnecessary SiO₂ film (silicon oxide film) formed by TEOS and deposited on structural members in a heat treatment apparatus, while damage to the structural members can be restrained.

Preferably, during the cleaning step, a temperature in the treatment vessel is in a range of from 100° C. to 300° C.

In addition, preferably, during the cleaning step, a pressure in the treatment vessel is equal to or more than 53200 Pa (400 Torr).

In addition, preferably, during the cleaning step, a supply amount of the HF gas is equal to or more than a supply amount of the NH₃ gas.

In addition, the present invention is a method of cleaning a heat treatment apparatus that deposits an AsSG film by means of TEOS on an object to be processed contained in a treatment vessel capable of forming a vacuum, the method comprising the step of: cleaning the heat treatment apparatus by supplying an HF gas and an NH₃ gas into the treatment vessel.

According to the present invention, a mixed gas of an HF gas and an NH₃ gas operating as a cleaning gas can rapidly, efficiently remove unnecessary AsSG film (arsenic silicate glass film) formed by TEOS and deposited on structural members in a heat treatment apparatus, while damage to the structural members can be restrained.

In addition, the present invention is a method of cleaning a heat treatment apparatus that deposits a BSG film by means of TEOS on an object to be processed contained in a treatment vessel capable of forming a vacuum, the method comprising the step of: cleaning the heat treatment apparatus by supplying an HF gas and an NH₃ gas into the treatment vessel.

According to the present invention, a mixed gas of an HF gas and an NH₃ gas operating as a cleaning gas can rapidly, efficiently remove unnecessary BSG film (boron silicate glass film) formed by TEOS and deposited on structural members in a heat treatment apparatus, while damage to the structural members can be restrained.

### BRIEF DESCRIPTION OF THE DRAWINGS

FIG. 1 is a block diagram showing an example of a heat treatment apparatus in which a cleaning method according to the present invention is performed;

FIG. 2 is a view showing comparisons between etching rates of a silicon oxide film formed by TEOS and etching rates of a quartz material;

FIG. 3 is a block diagram showing another example of a heat treatment apparatus in which a cleaning method according to the present invention is performed; and

FIG. 4 is a block diagram showing another example of a heat treatment apparatus in which a cleaning method according to the present invention is performed.

### DETAILED DESCRIPTION OF THE INVENTION

Hereinbelow, a method of cleaning a heat treatment apparatus in one embodiment according to the present invention will be described in detail, with reference to the accompanying drawings.

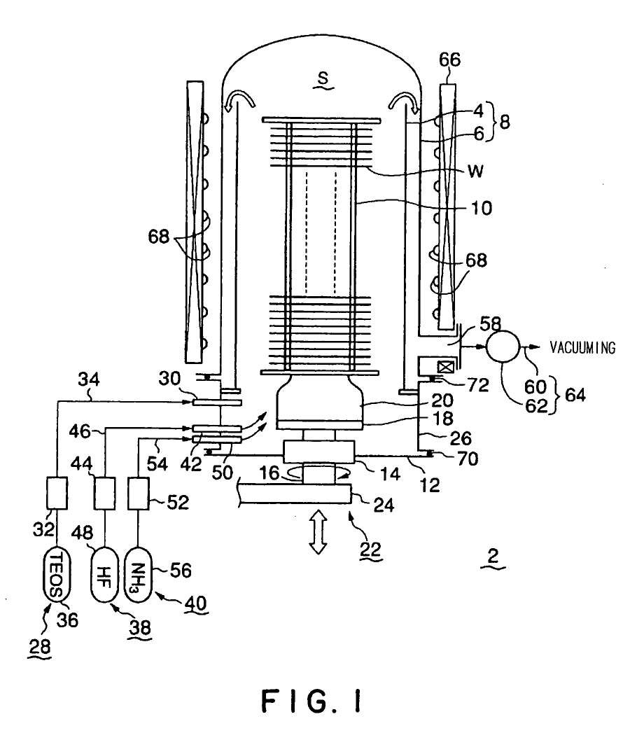

FIG. 1 is a block diagram showing an example of a heat treatment apparatus in which a cleaning method according to the present invention is performed. The heat treatment apparatus 2 is provided with a vertical treatment vessel 8 of a predetermined length made of quartz. The treatment vessel 8 is of a double tube structure including an inner tube 4 and an outer tube 6. A wafer boat 10 made of quartz is housed in a treatment space S formed in the inner tube 4. The wafer boat 10 serves as supporting means that holds an object to be processed. A plurality of objects to be processed such as semiconductor wafers W are held in the wafer boat 10 at predetermined pitches in a tier-like manner. The pitches may be either regular, or irregular depending on positions.

A cap 12 that opens and closes a lower part of the treatment vessel 8 is disposed therebelow. A rotating shaft 16 is provided on the cap 12 to pierce therethrough via a magnetic fluid seal 14. A rotating table 18 is disposed on an upper end of the rotating shaft 16. A heat-insulation cylinder 20 made of quartz is disposed on the table 18. The wafer boat 10 is placed on the heat-insulation cylinder 20. The rotating shaft 16 is mounted on an arm 24 of a boat elevator 22 capable of vertically moving. Thus, the rotating shaft 16 can vertically move together with the cap 12, the wafer boat 10, and so on. By means of a vertical movement of the boat elevator 22, the wafer boat 10 can be loaded into the treatment vessel 8 and unloaded therefrom through a bottom of treatment vessel 8. The wafer boat 10 may not be rotated but fixed.

A manifold 26 made of, e.g., stainless is joined to a lower opening of the treatment vessel 8. The manifold 26 is provided with a film-deposition gas supplying system 28 that supplies a gas for depositing a film. Specifically, the film-deposition gas supplying system 28 includes a film-deposition gas nozzle 30 piercing through the manifold 26. A gas supplying channel 34 is connected to the film-deposition gas nozzle 30. A flow controller 32 such as a massflow controller is disposed on the gas supplying channel 34. A TEOS source 36 that stores TEOS as a film-deposition gas is connected to the gas supplying channel 34. Thus, during a film-deposition treatment, a TEOS gas can be supplied into the treatment vessel 8, while a flow rate of the TEOS gas is controlled. In addition, an HF gas supplying system 38 and an NH₃ gas supplying system 40 are separately disposed on the manifold 26, so as to respectively introduce an HF gas and an NH₃ gas as a cleaning gas into the treatment vessel 8.

To be specific, the HF gas supplying system 38 includes an HF gas nozzle 42 piercing through the manifold 26. A gas supplying channel 46 is connected to the HF gas nozzle 42. A flow controller 44 such as a massflow controller is disposed on the gas supplying channel 46. An HF gas source 48 is connected to the gas supplying channel 46.

Similarly, the NH₃ gas supplying system 40 includes an NH₃ gas nozzle 50 piercing through the manifold 26. A gas supplying channel 54 is connected to the NH₃ gas nozzle 50. A flow rate controller 52 such as a massflow controller is disposed on the gas supplying channel 54. An NH₃ gas source 56 is connected to the gas supplying channel 54.

The respective gases supplied from the nozzles 30, 42, and 50 flow upward in the treatment space S (area in which wafers are housed) in the inner tube 4, turn round at a top part thereof, and flow downward in a gap between the inner tube 4 and the outer tube 6.

An exhaust port 58 is formed in a side wall at a bottom part of the outer tube 6, such that the exhaust port 58 is in communication with the gap between the inner tube 4 and the outer tube 6. A vacuum pumping system 64 including an exhaust channel 60 and a vacuum pump 62 is connected to the exhaust port 58. Thus, an inside of the treatment vessel 8 can be vacuumized.

A thermal barrier 66 is disposed around an outer circumference of the treatment vessel 8. A heater 68 as heating means is disposed on an inner side of the thermal barrier 66. Thus, the wafers W located inside the treatment vessel 8 can be heated to a predetermined temperature.

As to an overall size of the treatment vessel 8, in a case wherein a size of each of the wafers W for a film to be deposited is 8 inches, and the number of wafers to be held in the wafer boat 10 are about 150 (product wafers: about 130; dummy wafers: about 20), a diameter of the inner tube 4 is about 260 mm to about 270 mm, a diameter of the outer tube 6 is about 275 to about 285 mm, and a height of the treatment vessel 8 is about 1280 mm.

Alternatively, there may be a case in which the number of wafers to be held in the wafer boat 10 is about 25 to about 50, when a size of each of the wafers W is 12 inches. In this case, a diameter of the inner tube 4 is about 380 mm to 420 mm, a diameter of the outer tube 6 is about 440 mm to 500 mm, and a height of the treatment vessel 8 is about 800 mm. Note that these numerical values are simply given as examples.

Further, a sealing member 70 such as an O-ring is disposed in a gap between the cap 12 and the manifold 26 so as to seal the gap. A sealing member 72 such as an O-ring is disposed in a gap between the manifold 26 and a lower end of the outer tube 6 so as to seal the gap. Although not shown, a gas supplying system that supplies an inert gas such as an N₂ gas is disposed on the heat treatment apparatus 2.

Next, a method according to the present invention carried out by using the heat treatment apparatus as constituted above is described hereinbelow.

In the first place, there is explained a treatment for depositing an SiO₂ film on a surface of a semiconductor wafer W by means of TEOS.

A plurality of untreated semiconductor wafers W are held in the wafer boat 10 at predetermined pitches in a tier-like manner. When the boat elevator 22 is operated to move upward, the wafer boat 10 containing the wafers W is loaded into the treatment vessel 8 from below. The treatment vessel 8 is then hermetically closed by the cap 12. Then, an inside of the treatment vessel 8 is pre-heated. After the wafers W are loaded into the treatment vessel 8 as described above, a supply voltage to the heater 68 is increased, so that the wafers W are heated to a predetermined treatment temperature. Meanwhile, the inside of the treatment vessel 8 is vacuumized by the vacuum pumping system 64.

At the same time, TEOS is introduced from the TEOS source 36 of the film-deposition gas supplying system 28 into the treatment vessel 8 through the film-deposition gas nozzle 30, while the flow rate of the TEOS is controlled. With moving upward, the TEOS gas is thermally decomposed to deposit an SiO₂ film on a surface of each of the wafers W.

After the film-deposition treatment is completed, the supply of the TEOS gas is stopped, and the gas remaining in the treatment vessel 8 is purged by an N₂ gas or the like to be discharged outside. Subsequently, the wafer boat 10 is lowered, and the treated wafers W are taken out therefrom. The film-deposition treatment including the series of steps as described above is repeatedly carried out.

Due to a repetition of the film-deposition treatment, unnecessary film (SiO₂ film formed by TEOS) is deposited on surfaces of inner structures such as the treatment vessel 8 including the inner tube 4 and the outer tube 6, the wafer boat 10, and the heat-insulation cylinder 20. Thus, a cleaning treatment is regularly or irregularly performed so as to scratch the unnecessary film to remove the same.

In the cleaning treatment, the wafer boat 10 holding no wafer W is at first loaded into the treatment vessel 8. Then, an inside of the treatment vessel 8 is hermetically sealed. A temperature in the treatment vessel 8 is maintained at a predetermined temperature. Under this state, an HF gas whose flow rate is controlled is introduced as a cleaning gas from the HF gas nozzle 42 of the HF gas supplying system 38 into the treatment vessel 8. Simultaneously, an NH₃ gas whose flow rate is controlled is introduced from the NH₃ gas nozzle 50 of the NH₃ gas supply system 40 into the treatment vessel 8.

The HF gas and the NH₃ gas that have been separately introduced into the treatment vessel 8 are mixed with each other, while moving upward in the treatment vessel 8. The mixed gas removes by etching the silicon oxide film (SiO₂ film), which has been deposited on the respective surfaces of the heat-insulating cylinder 20, the wafer boat 10, the inner tube 4, the outer tube 6, and so on. In other words, the mixed gas cleans the heat treatment apparatus.

A period required for the cleaning treatment can be calculated by dividing an integrated quantity of unnecessary film by an etching rate. Preferable cleaning conditions are as follows: A treatment temperature is preferably in a range of from 100° C. to 300° C. A treatment pressure is preferably equal to or more than 53200 Pa (400 Torr). A supply amount of an HF gas is preferably equal to or more than a supply amount of an NH₃ gas. That is, an HF-gas rich state is preferred.

As stated above, by using a mixed gas of an HF gas and an NH₃ gas as a cleaning gas, unnecessary silicon oxide film formed by TEOS can be rapidly, efficiently etched and removed at a short time. Thus, a period needed for the cleaning treatment can be greatly reduced, as compared with a conventional case in which an HF gas is solely used as a cleaning gas. Therefore, even when a cleaning period is excessively prolonged because of a calculation error of the cleaning period to result in an overetching treatment, the excessive period for the overetching treatment is short. Consequently, damage to the inner structures, i.e., the inner tube 4, the outer tube 6, the wafer boat 10, the heat-insulation cylinder 20, and so on can be significantly restrained.

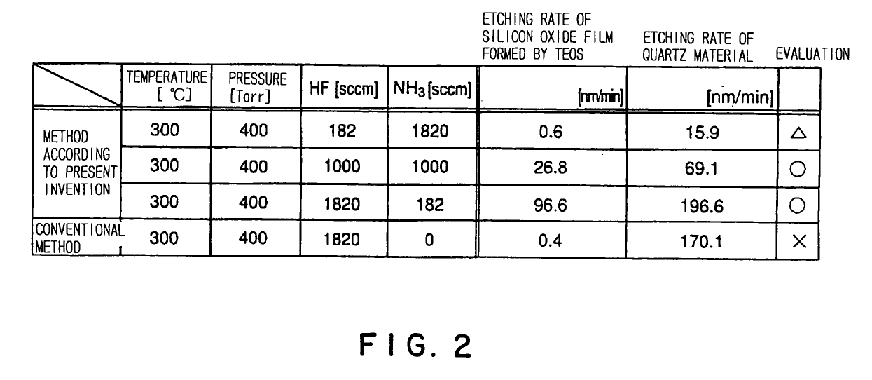

Experiments for comparing etching rates of a silicon oxide (SiO₂) film formed by TEOS with etching rates of a quartz (SiO₂) material used in the treatment vessel 8, the wafer boat 10, and the like were conducted under various conditions. The results and evaluations are explained below. FIG. 2 is a view showing comparisons between etching rates of a silicon oxide film formed by TEOS and etching rates of a quartz material. In these experiments, a temperature for a cleaning treatment was set at 300° C. which is a conventional, general temperature for a cleaning treatment. A treatment pressure was set at 400 Torr (53200 Pa). However, flow-rate ratios of an HF gas relative to an NH₃ gas were largely varied. Incidentally, 1 Torr equals to 133 Pa.

As clearly seen in FIG. 2, in the conventional case wherein the treatment temperature was 300° C., the treatment pressure was 400 Torr, the flow rate of the HF gas was 1820 sccm, and the flow rate of the NH₃ gas was zero, the etching rate for the silicon oxide film formed by TEOS was 0.4 nm/min, while the etching rate for the quartz material forming, e.g., the treatment vessel 8 was 170.1 nm/min. The evaluation of the conventional cleaning method was unacceptable, which is represented by a mark “x”. That is, since the etching rate for the silicon oxide film formed by TEOS is considerably small, the cleaning treatment should be carried out for a long time, which results in deterioration of an availability factor (deterioration of a throughput). Further, the small etching rate makes it difficult to precisely calculate an end point of the cleaning treatment. Thus, there may be a possibility that the cleaning treatment is erroneously prolonged, so that the quartz material of a larger etching rate may be badly damaged.

On the other hand, in the cases of the present invention wherein the mixed gas of the HF gas and the NH₃ gas were used as a cleaning gas, the evaluations were acceptable, which is represented by a mark “Δ”, or satisfactory, which is represented by a mark “◯”. In particular, in the case wherein the flow rate ratio of the HF gas relative to the NH₃ gas was 1000:1000, that is, wherein the supply amount of the HF gas was equal to the supply amount of the NH₃ gas, the etching rate for the silicon oxide film formed by TEOS was 26.8 nm/min. Further, in the case wherein the flow rate ratio of the HF gas relative to the NH₃ gas was 1820:182, that is, wherein the supply amount of the HF gas was more than the supply amount of the NH₃ gas (HF-gas rich state), the etching rate for the silicon oxide film formed by TEOS was 96.6 nm/min. These etching rates are as large as 67 to 240 times the etching rate obtained in the conventional method. Accordingly, a period required for the cleaning treatment can be reduced, so that an availability factor (throughput) of an apparatus can be improved.

In these cases, the etching rates for the quartz material were 69.1 nm/min and 196.6 nm/min, respectively. These etching rates are rather larger, similar to the etching rate (170.1 nm/min) obtained in the conventional method. However, as explained above, since the total period required for the cleaning treatment can be remarkably reduced, even if an end point of the cleaning treatment is miscounted, an erroneous, excessive cleaning treatment is performed for only a short period of time. Consequently, damage to the quartz material can be noticeably restrained. Herein, it is supposed that, for example, a 10% error may occur in calculating a period required for the cleaning treatment. In the conventional method, when a calculated cleaning period is 60 minutes, an excessive cleaning treatment may be carried out for six minutes. On the other hand, in the present invention, since a calculated cleaning period is 0.6 minutes (under the condition that the etching rate is 96.6 nm/min), an excessive cleaning treatment may be carried out only for 0.06 minutes (3.6 seconds). Accordingly, the method according to the present invention can significantly restrain the quartz material from being damaged.

In the case wherein the supply amount of the HF gas was 182 sccm and the supply amount of the NH₃ gas was 1820 sccm, that is, under an NH₃-gas rich state, the evaluation was “Δ”. To be more precise, the etching rate for the silicon oxide film formed by TEOS was 0.6 nm/min, which is 1.5 times larger than the etching rate of 0.4 nm/min obtained in the conventional method. Therefore, in this case as well, a sufficient effect can be anticipated, although it is impossible to expect the same effect as produced in the HF-gas rich state. In addition, the etching rate for the quartz material in this case was as small as 15.9 nm/min. Owing to this small etching rate, damage to the quartz material can be restrained, even when a cleaning treatment is excessively carried out.

Further to the above experiments, experiments for evaluating etching rates of an etching gas (mixed gas of an HF gas and an NH₃ gas) for a silicon oxide film formed by TEOS were additionally conducted. The results thereof are described below.

Experiments for a cleaning treatment were conducted under conditions that a treatment temperature was kept at 300° C. (the same as the temperature shown in FIG. 2), a treatment pressure was set at 150 Torr (lower than the pressure shown in FIG. 2), while a flow-rate ratio of an HF gas relative to an NH₃ gas was varied in a range of from 1:10 to 10:1, which was similar to FIG. 2. In these experiments, the silicon oxide film formed by TEOS was hardly etched. However, in an experiment conducted under the same conditions as above except that a treatment pressure was set larger than 400 Torr, the silicon oxide film formed by TEOS was sufficiently etched. Thus, it was confirmed that a pressure in the cleaning treatment is preferably equal to or more than 400 Torr.

In addition, experiments for a cleaning treatment were conducted under conditions that a treatment temperature was set at 400° C. (higher than the temperature shown in FIG. 2), a treatment pressure was set at 400 Torr (the same as the pressure shown in FIG. 2), while a flow-rate ratio of an HF gas relative to an NH₃ gas was varied in a range of from 1:10 to 10:1, which was similar to FIG. 2. In these experiments, the silicon oxide film formed by TEOS was hardly etched. Meanwhile, an experiment was conducted under conditions that a treatment temperature was set at 100° C. (lower than the temperature shown in FIG. 2), a treatment pressure was set at 400 Torr (the same as the pressure shown in FIG. 2), and a flow-rate ratio of an HF gas relative to an NH₃ gas was 1:1 (1000 sccm:1000 sccm). In this experiment, the silicon oxide film formed by TEOS was etched at an etching rate of 6 nm/min, and hence an effectiveness of the cleaning treatment was confirmed. Further, an experiment was conducted under the same conditions as above except that a temperature was a room temperature. In this experiment, the silicon oxide film formed by TEOS was not etched. Therefore, it was confirmed that a treatment temperature is preferably set in a range of from 100° C. to 300° C.

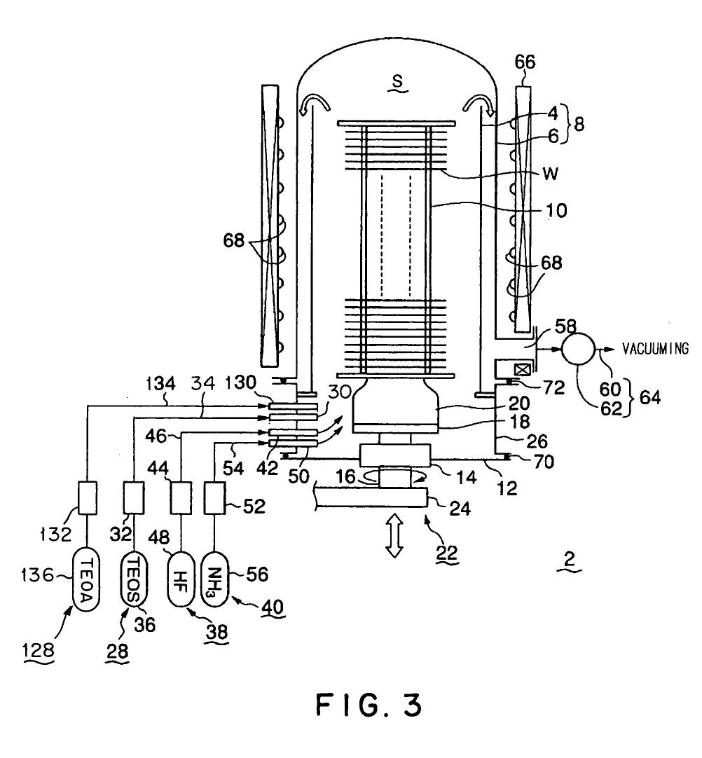

FIG. 3 is a block diagram showing another example of a heat treatment apparatus in which a cleaning method according to the present invention is performed. The heat treatment apparatus shown in FIG. 3 deposits an AsSG film (arsenic silicate glass film) by means of TEOS on an object to be processed, in a treatment vessel capable of forming a vacuum.

The heat treatment apparatus shown in FIG. 3 is provided with a second film-deposition gas supplying system 128 that supplies a TEOA gas for depositing a film. To be specific, the second film-deposition gas supplying system 128 includes a second film-deposition gas nozzle 130 piercing through a manifold 26. A gas supplying channel 134 is connected to the second film-deposition gas nozzle 130. A flow controller 132 such as a massflow controller is disposed on the gas supplying channel 134. A TEOA source 136 that stores TEOA as a second film-deposition gas is connected to the gas supplying channel 134. Thus, during a film-deposition treatment, the TEOA gas can be supplied into a treatment vessel 8, while a flow rate of the TEOA gas is controlled.

Other structures of the heat treatment apparatus shown in FIG. 3 are the same as those of the heat treatment apparatus shown in FIG. 1. Thus, in FIG. 3, the parts which are the same as those of the heat treatment apparatus shown in FIG. 1 are shown by the same reference numbers as those in FIG. 1, and their description is omitted.

Next, a method according to the present invention carried out by using the heat treatment apparatus as constituted above is described hereinbelow.

In the first place, there is explained a treatment for depositing an AsSG film on a surface of a semiconductor wafer W by means of TEOS and TEOA.

A plurality of untreated semiconductor wafers W are held in a wafer boat 10 at predetermined pitches in a tier-like manner. When a boat elevator 22 is operated to move upward, the wafer boat 10 containing the wafers W is loaded into a treatment vessel 8 from below. The treatment vessel 8 is then hermetically closed by a cap 12. Then, an inside of the treatment vessel 8 is pre-heated. After the wafers W are loaded into the treatment vessel 8 as described above, a supply voltage to a heater 68 is increased, so that the wafers W are heated to a predetermined treatment temperature. Meanwhile, the inside of the treatment vessel 8 is vacuumized by a vacuum pumping system 64.

At the same time, TEOS is introduced from a TEOS source 36 of a film-deposition gas supplying system 28 into the treatment vessel 8 through a film-deposition gas nozzle 30, while the flow rate of the TEOS is controlled. Similarly, TEOA is introduced from the TEOA source 136 of the second film-deposition gas supplying system 128 into the treatment vessel 8 through the second film-deposition gas nozzle 130, while the flow rate of the TEOA is controlled. With moving upward, the TEOS gas and the TEOA gas are thermally decomposed to deposit an AsSG film on a surface of each of the wafers W.

After the film-deposition treatment is completed, the supply of the TEOS gas and the TEOA gas is stopped, and the gas remaining in the treatment vessel 8 is purged by an N₂ gas or the like to be discharged outside. Subsequently, the wafer boat 10 is lowered, and the treated wafers W are taken out therefrom. The film-deposition treatment including the series of steps as described above is repeatedly carried out.

Due to a repetition of the film-deposition treatment, unnecessary film (AsSG film formed by TEOS and TEOA) is deposited on surfaces of inner structures such as the treatment vessel 8 including an inner tube 4 and an outer tube 6, the wafer boat 10, and a heat-insulation cylinder 20. Thus, a cleaning treatment is regularly or irregularly performed so as to scratch the unnecessary film to remove the same.

In the cleaning treatment, the wafer boat 10 holding no wafer W is at first loaded into the treatment vessel 8. Then, an inside of the treatment vessel 8 is hermetically sealed. A temperature in the treatment vessel 8 is maintained at a predetermined temperature. Under this state, an HF gas whose flow rate is controlled is introduced as a cleaning gas from an HF gas nozzle 42 of an HF gas supplying system 38 into the treatment vessel 8. Simultaneously, an NH₃ gas whose flow rate is controlled is introduced from an NH₃ gas nozzle 50 of an NH₃ gas supply system 40 into the treatment vessel 8.

The HF gas and the NH₃ gas that have been separately introduced into the treatment vessel 8 are mixed with each other, while moving upward in the treatment vessel 8. The mixed gas removes by etching the AsSG film formed by TEOS and TEOA, which has been deposited on the respective surfaces of the heat-insulating cylinder 20, the wafer boat 10, the inner tube 4, the outer tube 6, and so on. In other words, the mixed gas cleans the heat treatment apparatus.

A period required for the cleaning treatment can be calculated by dividing an integrated quantity of unnecessary film by an etching rate. Preferable cleaning conditions are as follows: A treatment temperature is preferably in a range of from 100° C. to 300° C. A treatment pressure is preferably equal to or more than 53200 Pa (400 Torr). A supply amount of an HF gas is preferably equal to or more than a supply amount of an NH₃ gas. That is, an HF-gas rich state is preferred.

As stated above, by using a mixed gas of an HF gas and an NH₃ gas as a cleaning gas, unnecessary arsenic silicate glass film formed by TEOS and TEOA can be rapidly, efficiently etched and removed at a short time. Thus, a period needed for the cleaning treatment can be greatly reduced, as compared with a conventional case in which an HF gas is solely used as a cleaning gas. Therefore, even when a cleaning period is excessively prolonged because of a calculation error of the cleaning period to result in an overetching treatment, the excessive period for the overetching treatment is short. Consequently, damage to the inner structures, i.e., the inner tube 4, the outer tube 6, the wafer boat 10, the heat-insulation cylinder 20, and so on can be significantly restrained.

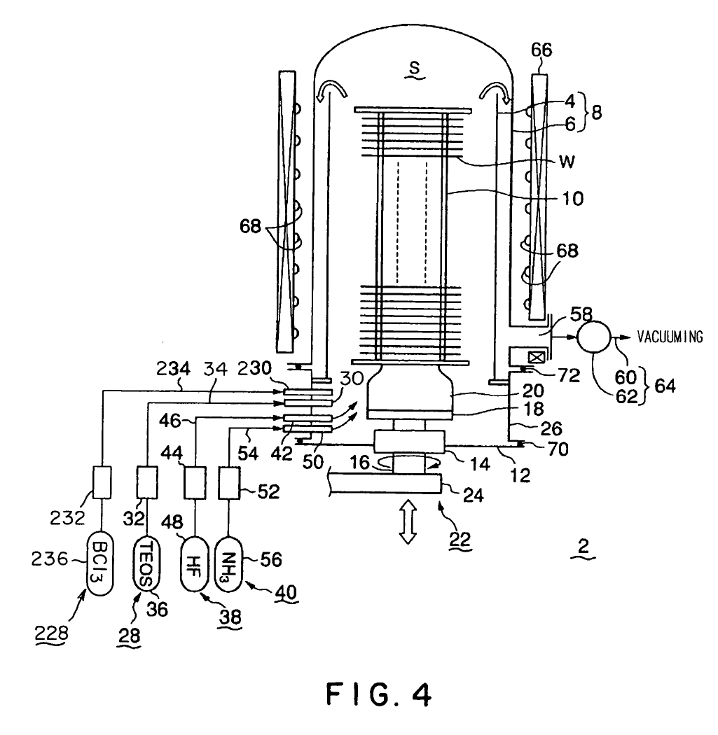

Further, FIG. 4 is a block diagram showing another example of a heat treatment apparatus in which a cleaning method according to the present invention is performed. The heat treatment apparatus shown in FIG. 4 deposits a BSG film (boron silicate glass film) by means of TEOS on an object to be processed, in a treatment vessel capable of forming a vacuum.

The heat treatment apparatus shown in FIG. 4 is provided with a third film-deposition gas supplying system 228 that supplies a BCl₃ gas for depositing a film. To be specific, the third film-deposition gas supplying system 228 includes a third film-deposition gas nozzle 230 piercing through a manifold 26. A gas supplying channel 234 is connected to the third film-deposition gas nozzle 230. A flow controller 232 such as a massflow controller is disposed on the gas supplying channel 234. A BCl₃ gas source 236 that stores a BCl₃ gas as a third film-deposition gas is connected to the gas supplying channel 234. Thus, during a film-deposition treatment, the BCl₃ gas can be supplied into a treatment vessel 8, while a flow rate of the BCl₃ gas is controlled.

Other structures of the heat treatment apparatus shown in FIG. 4 are the same as those of the heat treatment apparatus shown in FIG. 1. Thus, in FIG. 4, the parts which are the same as those of the heat treatment apparatus shown in FIG. 1 are shown by the same reference numbers as those in FIG. 1, and their description is omitted.

Next, a method according to the present invention carried out by using the heat treatment apparatus as constituted above is described hereinbelow.

In the first place, there is explained a treatment for depositing a BSG film on a surface of a semiconductor wafer W by means of TEOS and BCl₃.

A plurality of untreated semiconductor wafers W are held in a wafer boat 10 at predetermined pitches in a tier-like manner. When a boat elevator 22 is operated to move upward, the wafer boat 10 containing the wafers W is loaded into a treatment vessel 8 from below. The treatment vessel 8 is then hermetically closed by a cap 12. Then, an inside of the treatment vessel 8 is pre-heated. After the wafers W are loaded into the treatment vessel 8 as described above, a supply voltage to a heater 68 is increased, so that the wafers W are heated to a predetermined treatment temperature. Meanwhile, the inside of the treatment vessel 8 is vacuumized by a vacuum pumping system 64.

At the same time, TEOS is introduced from a TEOS source 36 of a film-deposition gas supplying system 28 into the treatment vessel 8 through a film-deposition gas nozzle 30, while the flow rate of the TEOS is controlled. Similarly, a BCl₃ gas is introduced from the BCl₃ source 236 of the third film-deposition gas supplying system 228 into the treatment vessel 8 through the third film-deposition gas nozzle 230, while the flow rate of the BCl₃ gas is controlled. With moving upward, the TEOS gas and the BCl₃ gas are thermally decomposed to deposit a BSG film on a surface of each of the wafers W.

After the film-deposition treatment is completed, the supply of the TEOS gas and the BCl₃ gas is stopped, and the gas remaining in the treatment vessel 8 is purged by an N₂ gas or the like to be discharged outside. Subsequently, the wafer boat 10 is lowered, and the treated wafers W are taken out therefrom. The film-deposition treatment including a series of these steps as described above is repeatedly carried out.

Due to a repetition of the film-deposition treatment, unnecessary film (BSG film formed by TEOS and BCl₃) is deposited on surfaces of inner structures such as the treatment vessel 8 including an inner tube 4 and an outer tube 6, the wafer boat 10, and a heat-insulation cylinder 20. Thus, a cleaning treatment is regularly or irregularly performed so as to scratch the unnecessary film to remove the same.

In the cleaning treatment, the wafer boat 10 holding no wafer W is at first loaded into the treatment vessel 8. Then, an inside of the treatment vessel 8 is hermetically sealed. A temperature in the treatment vessel 8 is maintained at a predetermined temperature. Under this state, an HF gas whose flow rate is controlled is introduced as a cleaning gas from an HF gas nozzle 42 of an HF gas supplying system 38 into the treatment vessel 8. Simultaneously, an NH₃ gas whose flow rate is controlled is introduced from an NH₃ gas nozzle 50 of an NH₃ gas supply system 40 into the treatment vessel 8.

The HF gas and the NH₃ gas that have been separately introduced into the treatment vessel 8 are mixed with each other, while moving upward in the treatment vessel 8. The mixed gas removes by etching the BSG film formed by TEOS and BCl₃, which has been deposited on the respective surfaces of the heat-insulating cylinder 20, the wafer boat 10, the inner tube 4, the outer tube 6, and so on. In other words, the mixed gas cleans the heat treatment apparatus.

A period required for the cleaning treatment can be calculated by dividing an integrated quantity of unnecessary film by an etching rate. Preferable cleaning conditions are as follows: A treatment temperature is preferably in a range of from 100° C. to 300° C. A treatment pressure is preferably equal to or more than 53200 Pa (400 Torr). A supply amount of an HF gas is preferably equal to or more than a supply amount of an NH₃ gas. That is, an HF-gas rich state is preferred.

As stated above, by using a mixed gas of an HF gas and an NH₃ gas as a cleaning gas, unnecessary boron silicate glass film formed by TEOS and BCl₃ can be rapidly, efficiently etched and removed at a short time. Thus, a period needed for the cleaning treatment can be greatly reduced, as compared with a conventional case in which an HF gas is solely used as a cleaning gas. Therefore, even when a cleaning period is excessively prolonged because of a calculation error of the cleaning period to result in an overetching treatment, the excessive period for the overetching treatment is short. Consequently, damage to the inner structures, i.e., the inner tube 4, the outer tube 6, the wafer boat 10, the heat-insulation cylinder 20, and so on can be significantly restrained.

In the foregoing description, the present invention is explained referring to a batch-type heat treatment apparatus of a double tube structure, which is taken as an example. Not limited thereto, the present invention can be applied to a heat treatment apparatus of a single tube structure, and a sheet-fed type heat treatment apparatus.

In addition, not limited to a semiconductor wafer, it goes without saying that an object to be processed may be a glass substrate, an LCD substrate, and so on.

1. A method of cleaning a heat treatment apparatus that deposits an SiO₂ film by means of TEOS on an object to be processed contained in a treatment vessel capable of forming a vacuum, the method comprising the step of:
cleaning the heat treatment apparatus by supplying an HF gas and an NH₃ gas into the treatment vessel.

2. The method of cleaning a heat treatment apparatus according to claim 1, wherein
during the cleaning step, a temperature in the treatment vessel is in a range of from 100° C. to 300° C.

3. The method of cleaning a heat treatment apparatus according to claim 1 or 2, wherein
during the cleaning step, a pressure in the treatment vessel is equal to or more than 53200 Pa (400 Torr).

4. The method of cleaning a heat treatment apparatus according to claim 1 or 2, wherein
during the cleaning step, a supply amount of the HF gas is equal to or more than a supply amount of the NH₃ gas.

5. A method of cleaning a heat treatment apparatus that deposits an AsSG film by means of TEOS on an object to be processed contained in a treatment vessel capable of forming a vacuum, the method comprising the step of:
cleaning the heat treatment apparatus by supplying an HF gas and an NH₃ gas into the treatment vessel.

6. A method of cleaning a heat treatment apparatus that deposits a BSG film by means of TEOS on an object to be processed contained in a treatment vessel capable of forming a vacuum, the method comprising the step of:
cleaning the heat treatment apparatus by supplying an HF gas and an NH₃ gas into the treatment vessel.

7. The method of cleaning a heat treatment apparatus according to claim 3, wherein
during the cleaning step, a supply amount of the HF gas is equal to or more than a supply amount of the NH₃ gas.
